(19) United States
(12) Patent Application Publication
(10) Pub. No.: US 2014/0055191 A1
(43) Pub. Date: Feb. 27, 2014

(54) LOW POWER RF SWITCH

(71) Applicant: HiDeep Inc, Gyeonggi-do (KR)

(72) Inventors: Bonkee Kim, Seoul (KR); Youngho Cho, Gyeonggi-do (KR); Donggu Im, Daejeon (KR); Bumkyum Kim, Daejeon (KR)

(73) Assignee: HiDeep Inc, Gyeonggi-do (KR)

(21) Appl. No.: 13/972,617

(22) Filed: Aug. 21, 2013

(30) Foreign Application Priority Data
Aug. 23, 2012 (KR) 10-2012-0092341

(51) Int. Cl. H03K 17/687

(52) U.S. Cl. CPC H03K 17/687
USPC 327/427

(57) ABSTRACT

Disclosed is a low power RF switch, and more particularly, disclosed is a low power RF switch which does not use a negative voltage when being driven. The low power RF switch includes: a switch unit which including a transistor which receives a high (H) control signal or a low (L) control signal and switches a signal flowing from one end to the other end thereof; a first voltage maintenance unit maintaining a constant voltage to one end of the transistor; and a second voltage maintenance unit maintaining a constant voltage to the other end of the transistor.

### CROSS-REFERENCE TO RELATED APPLICATION

The present application claims priority under 35 U.S.C. §119(e) of Korean Patent Application No. 10-2012-0092341 filed Aug. 23, 2012 the subject matters of which are incorporated herein by reference.

### BACKGROUND

1. Field

The present invention relates to a low power RF switch, and more particularly to a low power RF switch which does not use a negative voltage when being driven.

2. Description of Related Art

FIG. 1 shows an embodiment of a typical low power RF switch.

Referring to FIG. 1, the low power RF switch may be implemented by a transistor having a rapid response speed, for example, MOSFET. Also, the low power RF switch may be implemented not only by one transistor but a stacked transistor obtained by connecting in series multiple transistors. One end of a transistor M1 is connected to a first terminal 11, and the other end of the transistor M1 is connected to a second terminal 12. The on/off states of the transistor M1 is determined according to a control signal, and thus, the transistor M1 is able to perform switching operations.

The operation of the transistor M1 will be described in more detail. When the transistor M1 of the low power RF switch is in an on-state, a gate-source voltage (VGS) and a gate-drain voltage (VGD) are positive voltages (VDD), and a body-source voltage (VBS) and a body-drain voltage (VBD) are 0V. On the contrary to this, when the transistor M1 is in an off-state, the gate-source voltage (VGS) and the gate-drain voltage (VGD) are negative voltages (VSS), and the body-source voltage (VBS) and the body-drain voltage (VBD) are also negative voltages (VSS).

Accordingly, 0V (GND) is applied to the drain D, source S and body B of the transistor M1, and the positive voltage (VDD) is applied to the gate G. Therefore, the gate-source voltage (VGS) and the gate-drain voltage (VGD) of the transistor M1 becomes higher than a threshold voltage Vth of the transistor M1, so that the transistor M1 becomes an on-state. Contrarily, 0V (GND) signal is applied to the drain D and source S of the transistor M1, the negative voltage (VSS) is applied to the gate G and body B. Therefore, the gate-source voltage (VGS) and the gate-drain voltage (VGD) of the transistor M1 becomes less than the threshold voltage Vth of the transistor M1, so that the transistor M1 becomes an off-state.

For the above reason, the typical low power RF switch requires the positive voltage (VDD) and the negative voltage (VDD) so as to stably perform the on/off operation.

FIG. 2 shows a typical low power RF switch to which a negative voltage generator is adopted.

Referring to FIG. 2, the low power RF switch includes a negative voltage generator 20 which applies the negative voltage (VSS) to the transistors M1 and M2. The negative voltage generator 20 includes an oscillator 21 which oscillates a signal, a clock generator 22 which receives an oscillation signal from the oscillator 21 and generates a clock signal, and a negative voltage charge pump 23 which generates a negative voltage based on the output of the clock generator 22. The negative voltage generated by the negative voltage charge pump 23 is applied to the gate G or body B of the transistors M1 and M2 of the low power RF switch. If the negative voltage generator 20 is additionally provided for the purpose of applying the negative voltage to the low power RF switch, the low power RF switch is affected by switching noise occurring from the oscillator 21, the negative voltage charge pump 23, etc. Also, the low power RF switch has a power consumption disadvantage because the negative voltage generator 20 consumes the power. Besides, due to the negative voltage generator 20, it is difficult to implement a very small circuit.

### SUMMARY

One embodiment is a low power RF switch. The low power RF switch includes: a switch unit which switches a signal flowing between one end and the other end thereof in response to a control signal having a voltage higher than a ground voltage; a first voltage maintenance unit which maintains a constant voltage to the one end of the switch unit; and a second voltage maintenance unit which maintains a constant voltage to the other end of the switch unit.

### BRIEF DESCRIPTION OF THE DRAWINGS

Arrangements and embodiments may be described in detail with reference to the following drawings in which like reference numerals refer to like elements and wherein:

FIG. 1 shows an embodiment of a typical low power RF switch;

FIG. 2 shows a typical low power RF switch to which a negative voltage generator is adopted;

FIG. 3 shows a low power RF switch according to an embodiment of the present invention;

FIG. 4 shows an embodiment of a switch unit shown in FIG. 3;

FIG. 5 shows another embodiment of the switch unit shown in FIG. 3;

FIG. 6 shows an embodiment of a low power RF switch circuit shown in FIG. 3;

FIG. 7 shows another embodiment of the low power RF switch circuit shown in FIG. 3;

FIG. 8 shows further another embodiment of the low power RF switch circuit shown in FIG. 3; and

FIG. 9 shows yet another embodiment of the low power RF switch circuit shown in FIG. 3.

### DETAILED DESCRIPTION

A thickness or a size of each layer may be magnified, omitted or schematically shown for the purpose of convenience and clearness of description. The size of each component may not necessarily mean its actual size.

It should be understood that when an element is referred to as being ‘on’ or “under” another element, it may be directly on/under the element, and/or one or more intervening elements may also be present. When an element is referred to as being ‘on’ or ‘under’, ‘under the element’ as well as ‘on the element’ may be included based on the element.

An embodiment may be described in detail with reference to the accompanying drawings.

Prior to the description of a low power RF switch according to the embodiment of the present invention, when it is assumed that a positive voltage applied to a transistor is VDD in a case where the transistor is in an on-state with regard to a voltage signal applied to a transistor, it means that a high (H) signal has a voltage of about VDD/2 to VDD and a low (L) signal has a voltage of 0V (i.e., a ground signal) to about VDD/2. A negative voltage has an opposite polarity to that of the voltage VDD. A standard for dividing the voltage signal applied to the transistor into the high (H) signal and the low (L) signal is not necessarily fixed. The standard may be changed according to an implementation environment of the low power RF switch according to the embodiment of the present invention, for example, a magnitude of the applied positive voltage VDD or the characteristics of the transistor and the like.

Hereafter, a low power RF switch according to the embodiment of the present invention will be described with reference to the accompanying drawings.

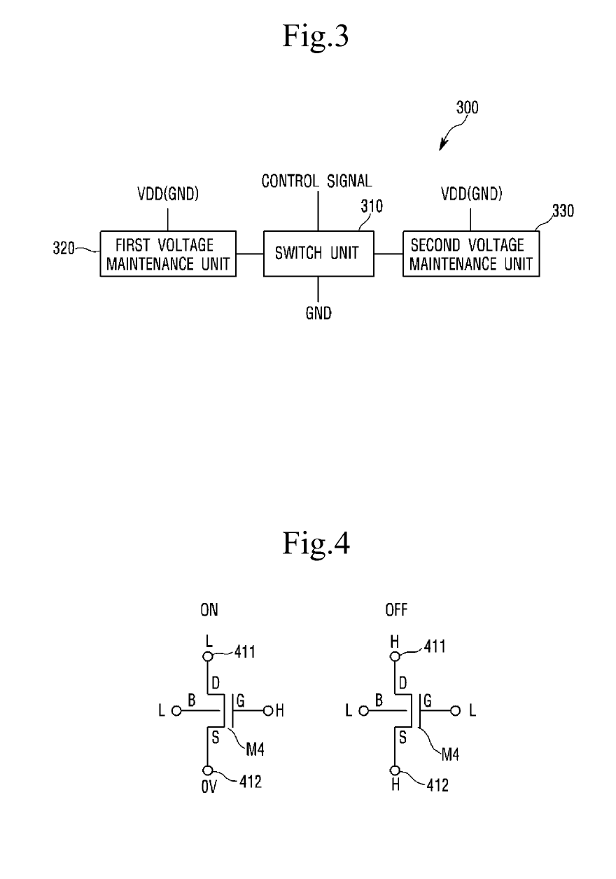

FIG. 3 shows a low power RF switch according to an embodiment of the present invention.

Referring to FIG. 3, a low power RF switch 300 includes a switch unit 310, a first voltage maintenance unit 320, and a second voltage maintenance unit 330. The switch unit 310 switches a signal flowing between one end and the other end thereof in response to a control signal having a voltage higher than a ground voltage. The first voltage maintenance unit 320 maintains a constant voltage to one end of the switch unit 310. The second voltage maintenance unit 330 maintains a constant voltage to the other end of the switch unit 310.

The switch unit 310 performs a switching operation in response to an input control signal. The control signal has the positive voltage VDD when the switch unit 310 is in the on-state. The control signal has a ground voltage GND when the switch unit 310 is in an off-state. The first voltage maintenance unit 320 maintains a predetermined voltage applied to one end of the switch unit 310. The second voltage maintenance unit 330 maintains a predetermined voltage applied to the other end of the switch unit 310. The control signal is transmitted, for example, in the form of a high (H) voltage or a low (L) voltage. The switch unit 310 performs an on/off operation in response to the voltage of the high or low control signal.

The first voltage maintenance unit 320 and the second voltage maintenance unit 330 receive the ground voltage GND respectively when the switch unit 310 is in the on-state, and receive the positive voltage VDD respectively when the switch unit 310 is in the off-state. Accordingly, one and the other ends of the switch unit 310 receive the positive voltage VDD or the ground voltage GND from the first voltage maintenance unit 320 and the second voltage maintenance unit 330 in response to the on/off operation of the switch unit 310.

More specifically, the first voltage maintenance unit 320 and the second voltage maintenance unit 330 transmit the ground voltage GND to one and the other ends of the switch unit 310 during the on-state of the switch unit 310, and transmit the positive voltage VDD to one and the other ends of the switch unit 310 during the off-state of the switch unit 310. Here, the voltage transmitted to one and the other ends of the switch unit 310 is maintained without oscillating by the first voltage maintenance unit 320 and the second voltage maintenance unit 330.

FIG. 4 shows an embodiment of a switch unit shown in FIG. 3.

Referring to FIG. 4, the switch unit 310 is located between a first terminal 411 and a second terminal 412, and includes a transistor M4 which switches on/off the connection of the first terminal 411 and the second terminal 412. That is, one end of the transistor M4 is connected to the first terminal 411, and the other end of the transistor M4 is connected to the second terminal 412. The gate of the transistor M4 receives the control signal. In other words, the drain D of the transistor M4 may be connected to the first terminal 411, the source S of the transistor M4 may be connected to the second terminal 412. Due to the characteristics of the transistor M4, the transistor M4 may be reversely connected between the first terminal 411 and the second terminal 412. The body B is connected to the ground. The first terminal 411 may be a load line unit connected to a load. The second terminal 412 may be grounded by being connected to the ground. For another example, the first terminal 411 may be an RF+ terminal connected to an RF input port to which a first signal is applied. The second terminal 20 may be an RF− terminal connected to an RF output port to which a second signal is applied. Besides, the first terminal 411 and the second terminal 412 may be used as a terminal having another form by a person having ordinary skill in the art.

First, when the transistor M4 is in the on-state, the high signal (H) is applied to the gate terminal G of the transistor M4, and the low (L) signal is applied to the drain terminal D, the source terminal S and the body terminal B. However, when the transistor M4 is in the off-state, the low (L) signal is applied to the gate terminal G and the body terminal B of the transistor M4, and the high (H) signal is applied to the drain terminal D and the source terminal S.

The operation of the transistor M4 according to the embodiment of the present invention is determined by the gate-drain voltage (VGD) of an electric potential difference between the gate terminal G and the drain terminal D, the gate-source voltage (VGS) of an electric potential difference between the gate terminal G and the source terminal S, the body-drain voltage (VBD) of an electric potential difference between the body terminal B and the drain terminal D, and the body-source voltage (VBS) of an electric potential difference between the body terminal B and the source terminal S.

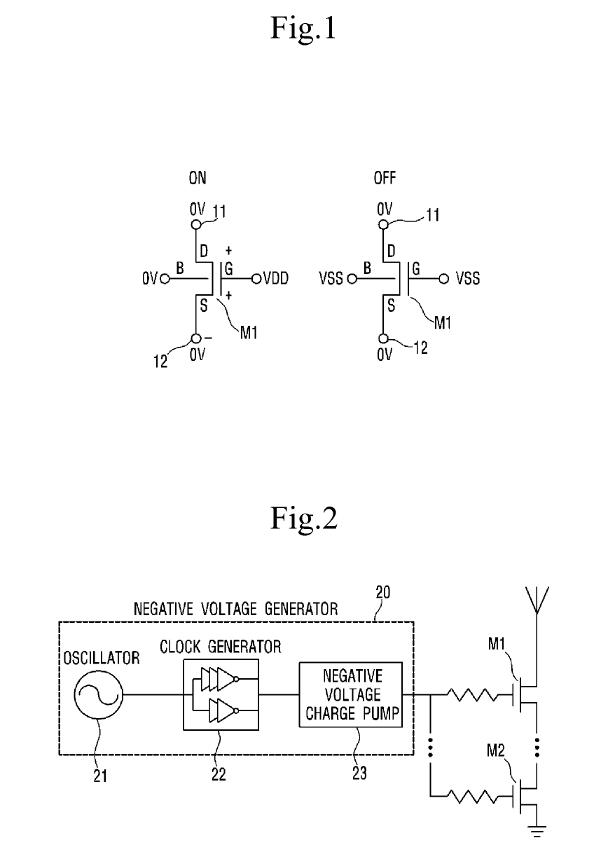

Referring to FIGS. 1 and 4, when the conventional transistor M1 and the transistor M4 according to the embodiment of the present invention are in the on-state, the voltages applied to the respective terminals are the same as each other, and thus the operations of them are also the same as each other. Contrary to this, when they are in the off-state, the voltages applied to the respective terminals are different from each other. However, when they are in the off-state, the gate-drain voltage (VGD) and the gate-source voltage (VGS) are the same as the negative value of VSS, and the body-drain voltage (VBD) and the body-source voltage (VBS) are also the same as the negative value of VSS. Consequently, the operations of the transistors are the same as each other.

In other words, despite the fact that the voltages applied to the respective terminals of the transistor M4 of the low power RF switch according to the embodiment of the present invention are different from the voltages applied to the respective terminals of the conventional transistor M1, the electric potential differences between the respective terminals are the same as each other, so that the two transistors perform the same operation. Accordingly, the low power RF switch according to the embodiment of the present invention does not use the negative voltage and is able to maintain the same power handling capability and linearity as those of a common switch using the negative voltage.

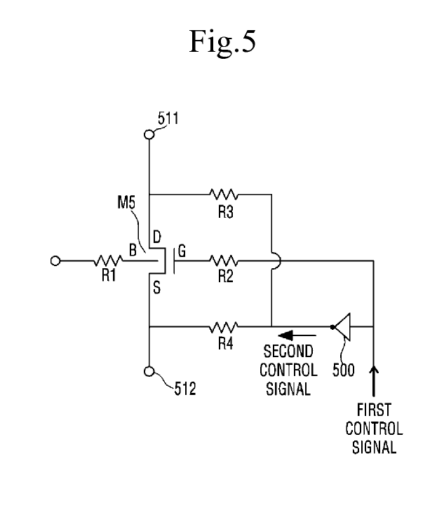

FIG. 5 shows another embodiment of the switch unit shown in FIG. 3.

Referring to FIG. 5, the low power RF switch according to the embodiment of the present invention includes a first terminal 511, a second terminal 512, and a transistor M5 which performs a switching operation between the first terminal 511 and the second terminal 512.

The on/off operation of the transistor M5 of the low power RF switch according to the embodiment of the present invention is performed by the low (L) signal and the high (H) signal without using the negative voltage. That is, the signal applied to the gate terminal G of the transistor M5 is converted, and then the converted signal is applied to the drain terminal D and the source terminal S of the transistor M5.

The on/off operation of the transistor M5 of the low power RF switch according to the embodiment of the present invention is performed not by the negative voltage but by a first control signal and a second control signal which are transmitted as the ground signal and a positive voltage signal. For this, the low power RF switch may further include a converter 500 which generates the second control by using the first control signal applied to the drain D and the source S of the transistor M5. The converter 500 generates the second control signal by converting the input first control signal applied to the gate G of the transistor M5, and then applies the generated second control signal to the drain D and the source S of the transistor M5.

A first resistor R1 and a second resistor R2 may be connected respectively to the body B and the gate G of the transistor M5. A third resistor R3 and a fourth resistor R4 may be connected respectively to the drain D and the source S. The third resistor R3 is located between the drain D and the converter 500, and the fourth resistor R4 is located between the source S and the converter 500. The first resistor R1 prevents the current from flowing to a low signal input terminal connected to the body B.

The second resistor R2, the third resistor R3 and the fourth resistor R4 allow the transistor M5 to stably perform its operation. When an alternating current signal which is swung between +3V and −3V is transmitted to the drain D and a high signal of +3V is transmitted to the gate G, an alternating current voltage is transmitted to the drain D. Accordingly, while the magnitude of the voltage is changed in real time, the voltage applied to the gate G is fixed at the high signal. As such, when the voltage of the drain D is changed, a difference between the voltage of the drain D and the voltage of the gate G may become less than a threshold voltage of the transistor M5. For example, when a voltage of +3V is transmitted to the drain D and a voltage of +3V is transmitted to the gate G, a voltage difference between the drain D and the gate G is 0V, and thus, less than the threshold voltage of the transistor M5, so that the transistor M5 becomes an off-state. However, when the second resistor R2 is connected to the gate G, a capacitor is formed between the source S and the gate G of the transistor M5 and between the gate G and the drain D of the transistor M5, so that a voltage between the source S and the gate G and a voltage between the gate G and the drain D are maintained constant due to the coupling operation of the formed capacitor. As a result, even though the high signal is input to the gate G and a current input to the drain D is swung between +3V and −3V, the voltage between the source S and the gate G and the voltage between the gate G and the drain D are maintained constant, so that the transistor M5 maintains the on-state.

Even when the transistor M5 is in the off-state, the off-state is maintained through the same process as the above. Also, in a case where a high or low signal is transmitted to the source S and the drain D of the transistor M5 by the first control signal and the second control signal, when the third resistor R3 and the fourth resistor R4 are not connected, the voltages of the source S and the drain D are fixed at a high or low signal voltage by the first and the second control signals. That is, even if a voltage is transmitted from the outside through the drain D, the voltage of the drain D becomes high or low by the first and the second control signals. Accordingly, even when the alternating current signal is applied through the first terminal 511, the voltage of the drain D of the transistor M5 becomes high or low by the first and the second control signals. In order to prevent this, the third resistor R3 and the fourth resistor R4 are connected to the source S and the drain D respectively. When the first control signal and the second control signal are transmitted to the source S and the drain D through the third resistor R3 and the fourth resistor R4, the first and the second control signals are not straight transmitted to the source S and the drain D by the third resistor R3 and the fourth resistor R4. Thus, when an alternating current voltage is transmitted through the first terminal 511, the alternating current voltage appears at the source S and the drain D.

Also, the second resistor R2, the third resistor R3 and the fourth resistor R4 are able to perform a function to prevent current from flowing from the converter 500 to the gate G, the drain D and the source S.

The converter 500 converts the voltages applied respectively to the drain D and the source S of the transistor M5 in such a manner as to be opposite to the voltage applied to the gate G. An inverter, etc., capable of converting the input control signal may be used as the converter 500.

The following description will focus on how to control the on/off of the transistor M5 by means of the voltage converted by the converter 500.

First, the operation in the on-state will be described. The first control signal is applied from the outside to the respective gates G of the transistor M5. Also, the first control signal is converted into the second control signal by the converter 500 and is applied to the drain D and the source S of the transistor M5. In other words, when the first control signal is in the on-state, the high (H) signal is applied to the gate G of the transistor M5 and the low (L) signal is applied to the drain D and the source S by the second control signal obtained by converting the first control signal. Therefore, the gate-source voltage (VGS) and the gate-drain voltage (VGD) have a positive value, so that the transistor M5 becomes in the on-state.

Next, the operation in the off-state will be described. An off-signal is applied as the first control signal from the outside, the low (L) signal is applied to the gate G of the transistor M5, and the high (H) signal is applied to the drain D and the source S by the second control signal obtained by converting the first control signal. Here, since the gate-source voltage (VGS) and the gate-drain voltage (VGD) have a negative value, the transistor M5 becomes in the off-state.

According to the embodiment of the present invention, the low (L) signal is applied to the body B of the transistor M5 when the control signal is in the on/off state.

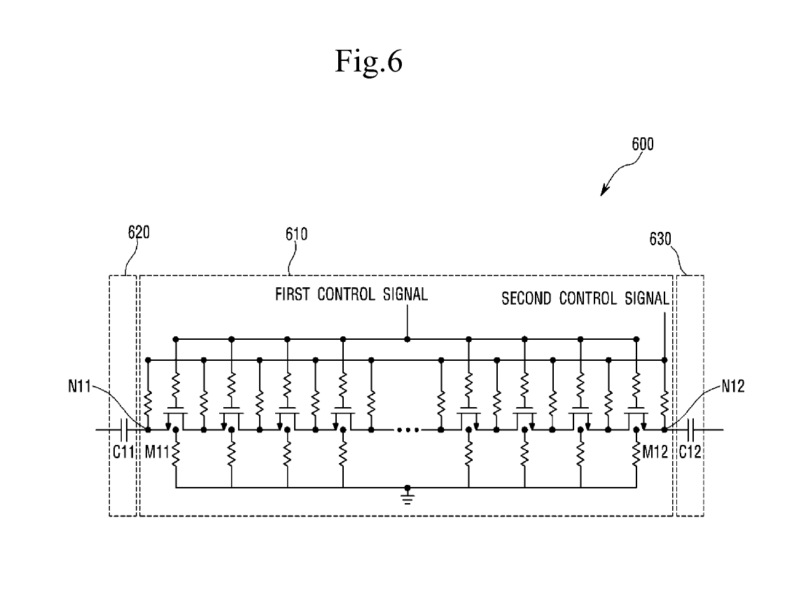

FIG. 6 shows an embodiment of a low power RF switch circuit shown in FIG. 3.

Referring to FIG. 6, a low power RF switch 600 includes a switch unit 610, a first voltage maintenance unit 620, and a second voltage maintenance unit 630.

The switch unit 610 has a stacked-structure formed by connecting in series a plurality of transistors. Also, the gate G and the body B of each transistor are connected in series to the resistor, and the source S and the drain D are also respectively connected to the resistor. The function of the resistor has been mentioned in the description of FIG. 5. The first control signal is transmitted to the gate of each transistor of the switch unit 610. The second control signal is transmitted to the drain of each transistor of the switch unit 610.

The first voltage maintenance unit 620 includes a first capacitor C11. One end of the first capacitor C11 is connected to a first node N11, and the other end of the first capacitor C11 is connected to a load line unit. The first node N11 is connected to the resistor and receives the second control signal through the resistor. The second voltage maintenance unit 630 includes a second capacitor C12. One end of the second capacitor C12 is connected to a second node N12, and the other end of the second capacitor C12 is connected to a load line unit. The second node N12 is connected to the resistor and receives the second control signal through the resistor.

The first capacitor C11 of the first voltage maintenance unit 620 and the second capacitor C12 of the second voltage maintenance unit 630 cause respectively the voltage of the second control signal which is transmitted as the low or high signal to be maintained, thereby allowing the switch unit 610 to stably perform its operation.

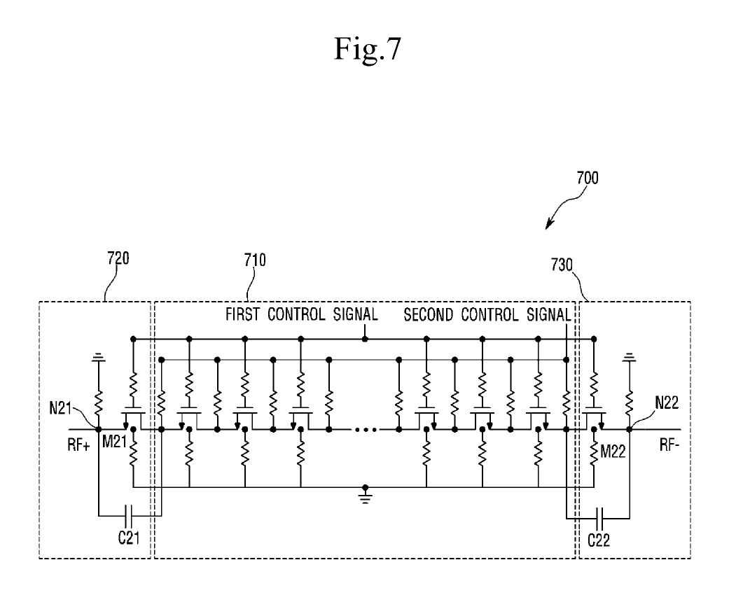

FIG. 7 shows another embodiment of a low power RF switch circuit shown in FIG. 3.

Referring to FIG. 7, a low power RF switch 700 includes a switch unit 710, a first voltage maintenance unit 720, and a second voltage maintenance unit 730.

The switch unit 710 has a stacked-structure formed by connecting in series a plurality of transistors. Also, the gate and the body B of each transistor are connected in series to the resistor, and the source and the drain are also respectively connected to the resistor. The function of the resistor has been mentioned in the description of FIG. 5. The first control signal is transmitted to the gate of each transistor of the switch unit 710. The second control signal is transmitted to the drain of each transistor of the switch unit 710.

The first voltage maintenance unit 720 includes a first transistor M21 and a first capacitor C21. One end of the first transistor M21 is connected to a first node N21. The one end of the first transistor M21, together with an input terminal RF+ to which the first signal is input, is connected to the ground through the resistor. The other end of the first transistor M21 is connected to one end of the switch unit 710. The gate of the first transistor M21 receives the first control signal, and the body of the first transistor M21 is connected to the ground. Here, the resistor is connected between the first node N21 and the ground, so that current flowing through the first node N21 is prevented from flowing to the ground. Also, the first capacitor C21 is connected between the source and the drain of the first transistor M21.

The second voltage maintenance unit 730 includes a second transistor M22 and a second capacitor C22. One end of the second transistor M22 is connected to a second node N22. The one end of the second transistor M22, together with an input terminal RF− to which the second signal is input, is connected to the ground through the resistor. The other end of the second transistor M22 is connected to one end of the switch unit 710. The gate of the second transistor M22 receives the first control signal, and the body of the second transistor M22 is connected to the ground. Here, the resistor is connected between the second node N22 and the ground, so that current flowing through the second node N22 is prevented from flowing to the ground. Also, the second capacitor C22 is connected between the source and the drain of the second transistor M22.

The first capacitor C21 and the second capacitor C22 cause a voltage between the first node N21 and the drain of the first transistor M21 or a voltage between the second node N22 and the drain of the second transistor M22 to be maintained constant, thereby preventing that a breakdown occurs due to the voltage difference between the source and the drain of the first transistor M21 and the voltage difference between the source and the drain of the second transistor M22 when the first and the second transistors M21 and M22 are in the off-state. The gates of the first and the second transistors M21 and M22 are connected in series to the resistor and receive the first control signal through the resistor.

The first voltage maintenance unit 720 and the second voltage maintenance unit 730 maintain the voltage between the source and the drain of the first transistor M21 and the voltage between the source and the drain of the second transistor M22 by using the first capacitor C21 and the second capacitor C22, so that the voltage of the second control signal which is transmitted as the low or high signal can be maintained. Thus, the switch unit 710 is able to stably perform its operation.

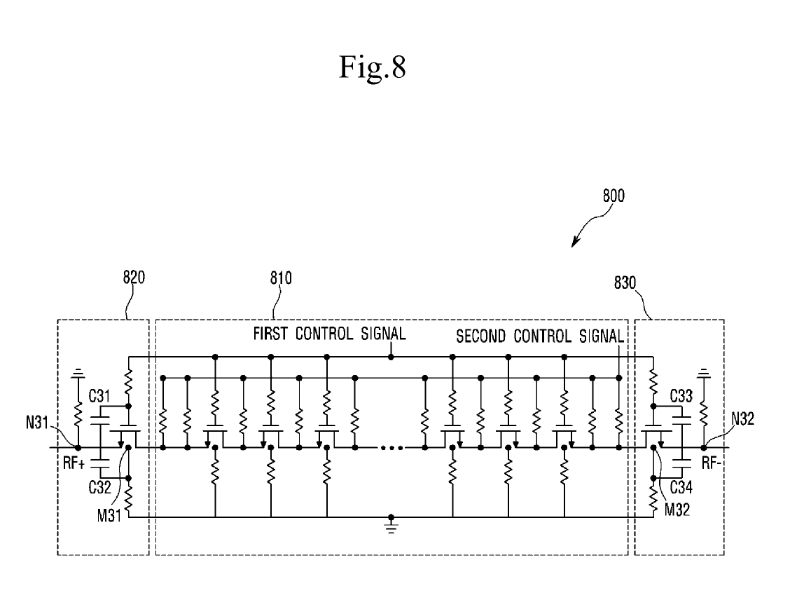

FIG. 8 shows further another embodiment of the low power RF switch circuit shown in FIG. 3.

Referring to FIG. 8, a low power RF switch 800 includes a switch unit 810, a first voltage maintenance unit 820, and a second voltage maintenance unit 830.

The switch unit 810 has a stacked-structure formed by connecting in series a plurality of transistors. Also, the gate and the body B of each transistor are connected in series to the resistor, and the source and the drain are also respectively connected to the resistor. The function of the resistor has been mentioned in the description of FIG. 5. The first control signal is transmitted to the gate of each transistor of the switch unit 810. The second control signal is transmitted to the drain of each transistor of the switch unit 810.

The first voltage maintenance unit 820 includes a first transistor M31, a first capacitor C31, and a second capacitor C32. One end of the first transistor M31 is connected to a first node N31. The one end of the first transistor M31, together with an input terminal RF+ to which the first signal is input, is connected to the ground through the resistor. The other end of the first transistor M31 is connected to one end of the switch unit 810. The gate of the first transistor M31 receives the first control signal, and the body of the first transistor M31 is connected to the ground. Here, the resistor is connected between the first node N31 and the ground, so that current flowing through the first node N31 is prevented from flowing to the ground when the switch unit 810 is in the on-state. Also, the first capacitor C31 is connected between the drain and the gate of the first transistor M31. The second capacitor C32 is connected between the drain and the body of the first transistor M31.

The second voltage maintenance unit 830 includes a second transistor M32, a third capacitor C33, and a fourth capacitor C34. One end of the second transistor M32 is connected to a second node N32. The one end of the second transistor M32, together with an input terminal RF− to which the second signal is input, is connected to the ground through the resistor. The other end of the second transistor M32 is connected to one end of the switch unit 810. The gate of the second transistor M32 receives the first control signal, and the body of the second transistor M32 is connected to the ground. Here, the resistor is connected between the second node N32 and the ground, so that current flowing through the second node N32 is prevented from flowing to the ground when the switch unit 810 is in the on-state. Also, the third capacitor C33 is connected between the drain and the gate of the second transistor M32. The fourth capacitor C34 is connected between the drain and the body of the second transistor M32.

The first capacitor C31 and the third capacitor C33 maintain the voltage between the drain and the gate of the first transistor M31 and the voltage between the drain and the gate of the second transistor M32, and the second capacitor C32 and the fourth capacitor C34 maintain the voltage between the drain and the body of the first transistor M31 and the voltage between the drain and the body of the second transistor M32. Accordingly, the on/off states of the first and the second transistors M31 and M32 can be surely maintained. The gates of the first and the second transistors M31 and M32 are connected in series to the resistor and receive the first control signal through the resistor.

The first and the second voltage maintenance units 820 and 830 maintain respectively the voltage of the second control signal which is transmitted as the low or high signal by using the first to the fourth capacitors C31 to C34. Accordingly, the switch unit 810 is able to stably perform its operation.

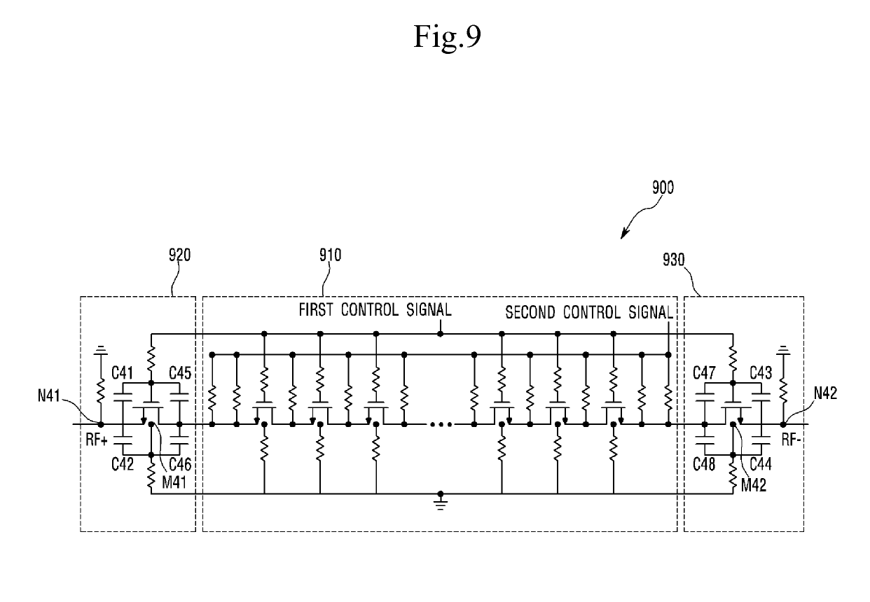

FIG. 9 shows yet another embodiment of the low power RF switch circuit shown in FIG. 3.

Referring to FIG. 9, a low power RF switch 900 includes a switch unit 910, a first voltage maintenance unit 920, and a second voltage maintenance unit 930. The switch unit 910 has a stacked-structure formed by connecting in series a plurality of transistors. Also, the gate and the body B of each transistor are connected in series to the resistor, and the source and the drain are also respectively connected to the resistor. The function of the resistor has been mentioned in the description of FIG. 5. The first control signal is transmitted to the gate of each transistor of the switch unit 910. The second control signal is transmitted to the drain of each transistor of the switch unit 910.

The first voltage maintenance unit 920 includes a first transistor M41, a first to a fourth capacitors C41, C42, C45, and C46. One end of the first transistor M41 is connected to a first node N41. The one end of the first transistor M41, together with an input terminal RF+ to which the first signal is input, is connected to the ground through the resistor. The other end of the first transistor M41 is connected to one end of the switch unit 910. The gate of the first transistor M41 receives the first control signal, and the body of the first transistor M41 is connected to the ground. Here, the resistor is connected between the first node N41 and the ground, so that current flowing through the first node N41 is prevented from flowing to the ground. Also, the first capacitor C41 is connected between the drain and the gate of the first transistor M41. The second capacitor C42 is connected between the drain and the body of the first transistor M41. The third capacitor C45 is connected between the source and the gate of the first transistor M41. The fourth capacitor C46 is connected between the source and the body of the first transistor M41.

The second voltage maintenance unit 930 includes a second transistor M42, a fifth to an eighth capacitors C43, C44, C47, and C48. One end of the second transistor M42 is connected to a second node N42. The one end of the second transistor M42, together with an input terminal RF− to which the second signal is input, is connected to the ground through the resistor. The other end of the second transistor M42 is connected to one end of the switch unit 910. The gate of the second transistor M42 receives the first control signal, and the body of the second transistor M42 is connected to the ground. Here, the resistor is connected between the second node N42 and the ground, so that current flowing through the second node N42 is prevented from flowing to the ground. Also, the fifth capacitor C43 is connected between the drain and the gate of the second transistor M42. The sixth capacitor C44 is connected between the drain and the body of the second transistor M42. The seventh capacitor C47 is connected between the source and the gate of the second transistor M42. The eighth capacitor C48 is connected between the source and the body of the second transistor M42.

The first to the fourth capacitors C41, C42, C45, and C46 maintain the voltages between the drain and the gate, between the drain and the body, between the source and gate, and between the source and the body of the first transistor M41. The fifth to the eighth capacitors C43, C44, C47, and C48 maintain the voltages between the drain and the gate, between the drain and the body, between the source and gate, and between the source and the body of the second transistor M42. Accordingly, the on/off states of the first and the second transistors M41 and M42 can be surely maintained. The gates of the first and the second transistors M41 and M42 are connected in series to the resistor and receive the first control signal through the resistor. As a result, the first and the second voltage maintenance units 920 and 930 maintain respectively the voltage of the second control signal which is transmitted as the low or high signal by using the first to the eighth capacitors C41 to C48. Accordingly, the switch unit 910 is able to stably perform its operation.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to affect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A low power RF switch comprising:
a switch unit which switches a signal flowing between one end and the other end thereof in response to a control signal having a voltage higher than a ground voltage;
a first voltage maintenance unit which maintains a constant voltage to the one end of the switch unit; and
a second voltage maintenance unit which maintains a constant voltage to the other end of the switch unit.

2. The low power RF switch of claim 1, wherein the control signal is transmitted in the form of a high (H) voltage or a low (L) voltage.

3. The low power RF switch of claim 1, wherein the switch unit comprises a transistor, wherein, when the transistor is in an on-state, a gate G of the transistor receives the high (H) control signal, a body B receives the low (L) control signal, and a source S and a drain D receive the low (L) control signal, and wherein, when the transistor is in an off-state, the gate G of the transistor receives the low (L) control signal, the body B receives the low (L) control signal, and the source S and the drain D receive the high (H) control signal.

4. The low power RF switch of claim 3, wherein the control signal input to the source S and the drain D is obtained by inverting the control signal input to the gate G.

5. The low power RF switch of claim 1, wherein the switch unit comprises at least a first transistor and a second transistor, wherein the first transistor and the second transistor are connected between the first voltage maintenance unit and the second voltage maintenance unit, and wherein a source S of the first transistor is connected to a drain D of the second transistor.

6. The low power RF switch of claim 1, wherein the first voltage maintenance unit comprises a first capacitor, wherein one end of the first capacitor is connected to the one end of the switch unit and maintains a voltage applied to the one end of the switch unit, wherein the second voltage maintenance unit comprises a second capacitor, and wherein one end of the second capacitor is connected to the other end of the switch unit and maintains a voltage applied to the other end of the switch unit.

7. The low power RF switch of claim 1,
wherein the first voltage maintenance unit comprises a first transistor and a first capacitor, wherein a drain D of the first transistor is connected to an input terminal, wherein a source S of the first transistor is connected to one end of the switch unit, wherein a gate G of the first transistor is connected to an input terminal to which a control signal is input, wherein a body B of the first transistor is connected to an input terminal to which a low (L) control signal is input, wherein the first capacitor is connected between the drain D and the source S of the first transistor,
wherein the second voltage maintenance unit comprises a second transistor and a second capacitor, wherein a drain S of the second transistor is connected to one end of the switch unit, wherein a source S of the of the second transistor is connected to an output terminal, wherein a gate G of the second transistor is connected to an input terminal to which a control signal is input, wherein a body B of the second transistor is connected to an input terminal to which a low (L) control signal is input, and wherein the second capacitor is connected between the drain D and the source S of the second transistor.

8. The low power RF switch of claim 1,
wherein the first voltage maintenance unit further comprises a first transistor of which a drain D is connected to an input terminal to which a first signal is input and of which a source S is connected to one end of the switch unit, a first capacitor which is connected to the drain D and a gate G of the first transistor, and a second capacitor which is connected to the drain D and a body B of the first transistor,
wherein the second voltage maintenance unit further comprises a second transistor of which a drain D is connected to one end of the switch unit and of which a source S is connected to an input terminal to which a second signal is input, a third capacitor which is connected to the drain D and a gate G of the second transistor, and a fourth capacitor which is connected to the drain D and a body B of the second transistor.

9. The low power RF switch of claim 8, further comprising a fifth capacitor which is connected to the source S and the gate G of the first transistor, a sixth capacitor which is connected to the source S and the body B of the first transistor, a seventh capacitor which is connected to the source S and the gate G of the second transistor, and an eighth capacitor which is connected to the source S and the body B of the second transistor,

10. The low power RF switch of claim 3, wherein a resistor is connected in series between the gate G of the transistor and an input terminal transmitting the control signal to the gate G, and wherein a resistor is connected in series between the body B of the transistor and an input terminal transmitting the control signal to the body B.

11. The low power RF switch of claim 3, wherein a resistor is connected in series between the drain D of the transistor and an input terminal transmitting the control signal to the drain D, and wherein a resistor is connected in series between the source S of the transistor and an input terminal transmitting the control signal to the source S.
